(19) United States
(12) Patent Application Publication
(10) Pub. No.: US 2025/0285940 A1
(43) Pub. Date: Sep. 11, 2025

(54) PRINTED CIRCUIT BOARD

(71) Applicant: SAMSUNG ELECTRO-MECHANICS CO., LTD., Suwon-si (KR)

(72) Inventors: Chi Hyeon JEONG, Suwon-si (KR); Jong Pil KIM, Suwon-si (KR); Chul Mun KANG, Suwon-si (KR); Seok Hwan KIM, Suwon-si (KR)

(73) Assignee: SAMSUNG ELECTRO-MECHANICS CO., LTD., Suwon-si (KR)

(21) Appl. No.: 18/958,654

(22) Filed: Nov. 25, 2024

(30) Foreign Application Priority Data
Mar. 6, 2024 (KR) 10-2024-0031824

(51) Int. Cl. H01L 23/48; H01L 23/00; H01L 25/065

(52) U.S. Cl. CPC H01L 23/481; H01L 25/0655; H01L 24/16; H01L 2224/16227; H01L 2224/16235; H01L 2924/1903

(57) ABSTRACT

The present disclosure relates to a printed circuit board including: a substrate having a cavity; and a via structure at least partially disposed in the cavity, and the via structure includes a glass layer, a first optical waveguide pattern disposed on the glass layer, and a dielectric layer disposed on the glass layer and covering at least a portion of the first optical waveguide pattern.

### CROSS-REFERENCE TO RELATED APPLICATION(S)

This application claims the benefit of priority to Korean Patent Application No. 10-2024-0031824 filed on Mar. 6, 2024, in the Korean Intellectual Property Office, the disclosure of which is incorporated herein by reference in its entirety.

### TECHNICAL FIELD

The present disclosure relates to a printed circuit board.

### BACKGROUND

Since traditional organic packages have low costs and mature technology, the organic packages may have high reliability, but recently, with the increase in chip speed, it has become difficult to sufficiently implement transmission speed. In addition, the traditional organic packages may make it difficult to secure sufficient transparency, and may have limitations in forming optical waveguides.

### SUMMARY

An aspect of the present disclosure is to provide a printed circuit board which may secure sufficient transparency and may easily form an optical waveguide for optical signal transmission.

One of the various solutions provided through the present disclosure is to form a via structure including an optical waveguide pattern using a glass layer and insert the via structure into a cavity of a substrate, thereby enabling interlayer optical signal transmission.

For example, a printed circuit board according to an example embodiment may include: a substrate having a cavity; and a via structure at least partially disposed in the cavity, and the via structure may include a glass layer, a first optical waveguide pattern disposed on the glass layer, and a dielectric layer disposed on the glass layer and covering at least a portion of the first optical waveguide pattern.

Another of the various solutions provided through the present disclosure is to allow for interlayer optical signal transmission by inserting a via structure including an optical waveguide pattern into a cavity of a substrate including a glass substrate.

For example, a printed circuit board according to an example embodiment may include a substrate including one or more insulating layers and having a cavity penetrating through at least a portion of at least one of the one or more insulating layers; and a via structure at least partially disposed in the cavity, and including a first optical waveguide pattern, and the one or more insulating layers may include a glass substrate.

One of the various effects of the present disclosure is to provide a printed circuit board that may secure sufficient transparency and may easily form an optical waveguide for transmitting an optical signal.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a perspective view schematically illustrating an example of a printed circuit board;

FIG. 4 is a schematic a cut cross-sectional view taken along line I-I′ of the printed circuit board of FIG. 3;

FIG. 5 is a perspective view schematically illustrating an example of the via structure of FIG. 3;

FIG. 6 is a perspective view schematically showing another example of the via structure of FIG. 3;

FIG. 7 is a process diagram schematically illustrating an example of manufacturing the printed circuit board of FIG. 3;

FIG. 8 is a perspective view schematically illustrating another example of a printed circuit board;

FIG. 9 is a schematic a cut cross-sectional view taken along line II-II′ of the printed circuit board of FIG. 8;

FIG. 10 is a cross-sectional view schematically illustrating another example of a printed circuit board;

FIG. 11 is a cross-sectional view schematically illustrating another example of a printed circuit board;

FIG. 12 is a cross-sectional view schematically illustrating another example of a printed circuit board;

FIG. 13 is a cross-sectional view schematically illustrating another example of a printed circuit board;

FIG. 14 is a process diagram schematically illustrating an example of forming a wiring pattern for transmitting an electric signal to a substrate and an optical waveguide pattern for transmitting an optical signal; and

FIG. 15 is a process diagram schematically illustrating an example of manufacturing a printed circuit board using a mirror structure.

### DETAILED DESCRIPTION

Hereinafter, the present disclosure will be described with reference to the accompanying drawings. In the drawings, the shape and size of the elements may be exaggerated or reduced for clearer description.

### Electronic Device

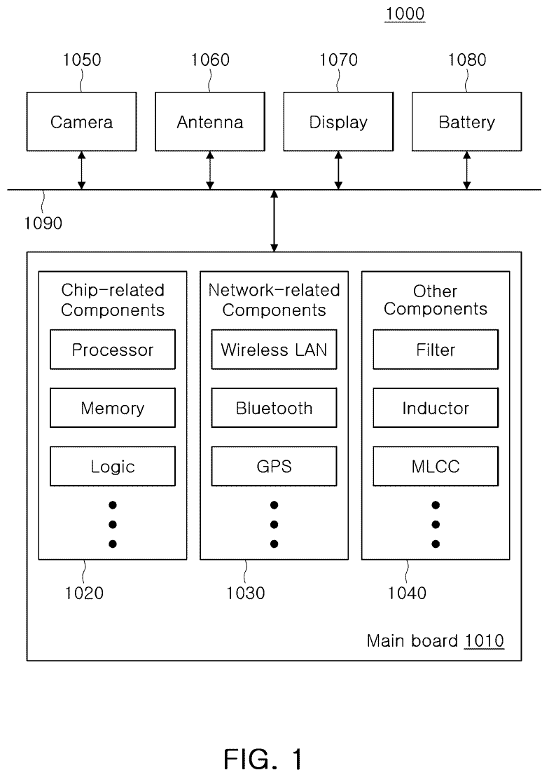

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

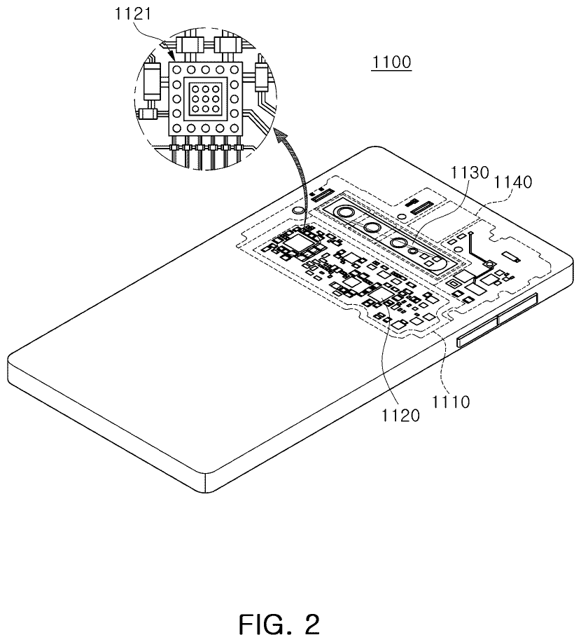

FIG. 2 is a perspective view schematically illustrating an example of an electronic device.

Referring to FIG. 2, an electronic device may be, for example, a smartphone 1100. A motherboard 1110 may be accommodated in the smartphone 1100, and various components 1120 may be physically and/or electrically connected to the motherboard 1110. Furthermore, other components that may or may not be physically and/or electrically connected to the motherboard 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

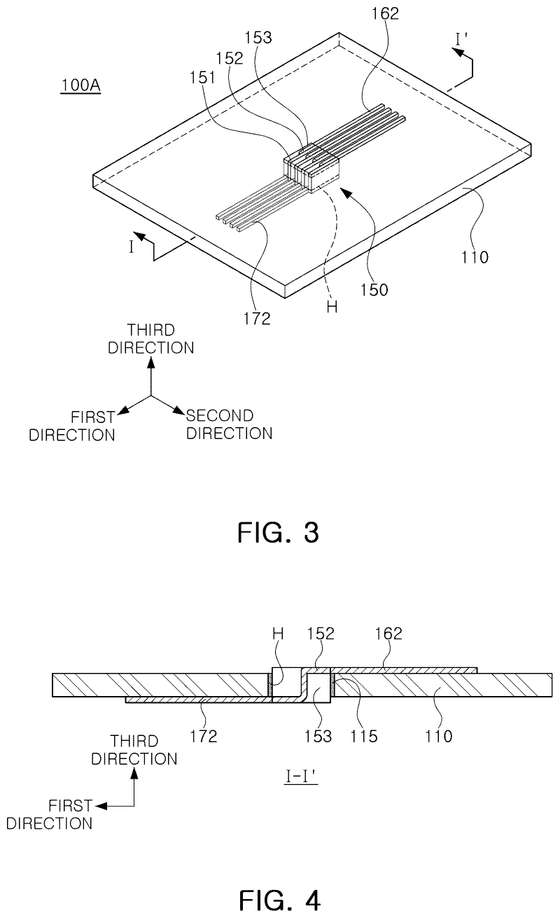

FIG. 3 is a perspective view schematically illustrating an example of a printed circuit board.

FIG. 4 is a schematic a cut cross-sectional view taken along line I-I′ of the printed circuit board of FIG. 3.

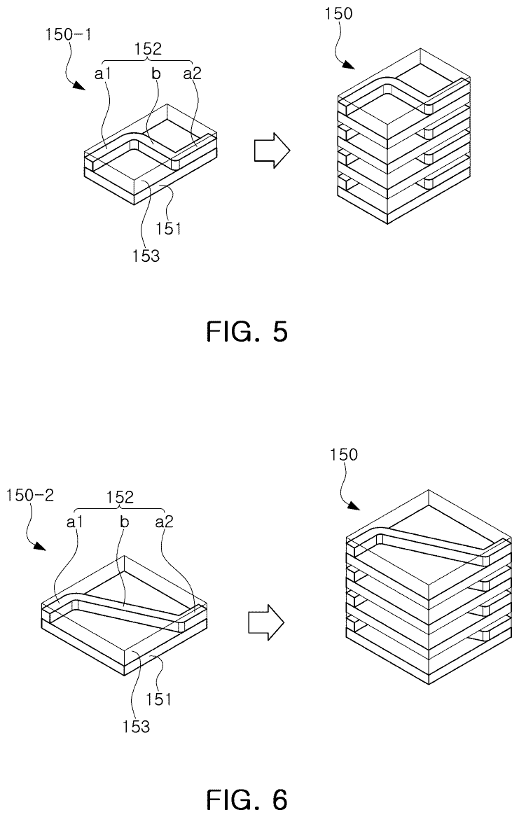

FIG. 5 is a perspective view schematically illustrating an example of the via structure of FIG. 3.

FIG. 6 is a perspective view schematically showing another example of the via structure of FIG. 3.

Referring to the drawings, a printed circuit board 100A according to an example embodiment may include a substrate 110 having a cavity H and a via structure 150 at least partially disposed in the cavity H. The via structure 150 may include a first optical waveguide pattern 152, and the first optical waveguide pattern 152 may connect second and third optical waveguide patterns 162 and 172 disposed on an upper surface and a lower surface of the substrate 110, respectively. The via structure 150 may include a glass layer 151, a first optical waveguide pattern 152 disposed on the glass layer 151, and a dielectric layer 153 disposed on the glass layer 151 and covering at least a portion of the first optical waveguide pattern 152. The via structure 150 may be disposed so that at least a portion of a surface on which the first optical waveguide pattern 152 of the glass layer 151 is disposed is substantially perpendicular to at least a portion of the upper surface or the lower surface of the substrate 110.

In this manner, the printed circuit board 100A according to an example embodiment may have a structure in which the first optical waveguide pattern 152 is formed on the glass layer 151 and then the via structure 150 covered with a dielectric layer 153 is separately formed and inserted into the cavity H of the substrate 110. Therethrough, interlayer optical signal transmission may be enabled in the substrate 110. For example, the second and third optical waveguide patterns 162 and 172 formed on different layers of the substrate 110 may be connected to each other through the first optical waveguide pattern 152 of the via structure 150, thereby providing a printed circuit board having a structure facilitating optical signal transmission. Specifically, the optical signal transmission may be more advantageous due to the transparency of the glass layer 151. For example, the data transmission amount and speed may be improved. Additionally, the substrate 110 may include a glass substrate, in which case the optical signal transmission may be more advantageous due to the transparency. Additionally, warpage properties thereof may be more excellent, and the flatness thereof may be excellent, so that the printed circuit board 100A may be more advantageous for forming a fine pitch circuit.

Meanwhile, the first optical waveguide pattern 152 may include first and second ends a1 and a2 and a connection portion b connecting the first and second ends a1 and a2. The first end a1 may be disposed on an upper side of the via structure 150, and a portion of the first end a1 may be exposed to a first side surface of the dielectric layer 153 in a first direction, substantially parallel to at least a portion of the upper surface or the lower surface of the substrate 110. The second end a2 may be disposed on a lower side of the via structure 150, and a portion of the second end a2 may be exposed to a second side surface opposite to the first side surface of the dielectric layer 153 in the first direction. The connection portion b may connect the first and second ends a1 and a2 in a third direction, substantially perpendicular to at least a portion of the upper surface or the lower surface of the substrate 110. The connection portion b may be curved in each of the portions connected to the first and second ends a1 and a2. For example, a radius of curvature of the curved portion may be adjusted in a structure proposed for Total Internal Reflection (TIR). In this manner, the via structure 150 may be inserted substantially vertically into the cavity H of the substrate 110, which may have a structure more advantageous for the interlayer optical signal connection.

Meanwhile, the via structure 150 may be inserted into the cavity H of the substrate 110 in the form of a stack body in which a plurality of unit via structures 150-1 or 150-2 are stacked. The via structure 150 in the form of the stack body may include a structure in which the glass layer 151, the first optical waveguide pattern 152 and the dielectric layer 153 are alternately disposed in this order. For example, when the via structure 150 in the form of the stack body is inserted into the cavity H of the substrate 110, the glass layer 151, the first optical waveguide pattern 152 and the dielectric layer 153 may be alternately disposed in this order in a second direction, substantially parallel to at least a portion of the upper surface or the lower surface of the substrate 110 but substantially perpendicular to the first direction. The shapes of the first and second ends a1 and a2 and the connection portion b in the via structure 150 may be variously modified depending on the cavity H. For example, the unit via structure 150-1 may have a structure in which a length thereof is relatively larger than a width thereof, in which case the first and second ends a1 and a2 may be formed to be relatively longer than the connection portion b. Alternatively, the unit via structure 150-2 may have substantially the same length and width, in which case the connection portion b may be formed to be relatively longer than the first and second ends a1 and a2.

Meanwhile, the cavity H may be a through-cavity penetrating between the upper surface and the lower surface of the substrate 110. In this case, a portion of the via structure 150 may protrude upward from the cavity H. For example, the first end a1 or the second end a2 of the first optical waveguide pattern 152 may be exposed from one portion of a protruding portion of the via structure 150 to the first side surface or the second side surface of the dielectric layer 153. Additionally, another portion of the via structure 150 may protrude downward from the cavity H. For example, the second end a2 or the first end a1 of the first optical waveguide pattern 152 may be exposed to the second side surface or the first side surface of the dielectric layer 153 from the other portion of the protruding portion of the via structure 150. Therethrough, the first optical waveguide pattern 152 may be easily connected to second and third optical waveguide patterns 162 and 172 respectively disposed on the upper surface and the lower surface of the substrate 110.

Meanwhile, each of the first to third optical waveguide patterns 152, 162 and 172 and the dielectric layer 153 may include transparent dielectrics, identical to or different from each other. Accordingly, the optical signal transmission may be possible. Here, in the transparent dielectric in the present disclosure, a transmittance may be measured in the visible light range (400 nm to 700 nm), so that the transmittance thereof is approximately 90% or more. A refractive index of the first optical waveguide pattern 152 may be greater than a refractive index of the dielectric layer 153 surrounding the first optical waveguide pattern 152. Accordingly, the dielectric layer 153 may effectively prevent an optical signal transmitted through the first optical waveguide pattern 152 from being transmitted to the outside. At least a portion of a remaining space excluding a space in which the via structure 150 of the cavity H is disposed may be filled with a filler 115, and the filler 115 may also include a transparent dielectric. Accordingly, this structure may be more advantageous for the optical signal transmission.

Hereinafter, components of a printed circuit board 100A according to an example embodiment will be described in more detail with reference to the drawings.

The substrate 110 may include one or more insulating layers. At least one of the one or more insulating layers may include a glass substrate. The glass substrate may include glass, which is an amorphous solid. The glass may include, for example, pure silicon dioxide (about 100% SiO₂), soda-lime glass, borosilicate glass, and alumino-silicate glass. However, the present disclosure is not limited thereto, and alternative glass materials, for example, fluorine glass, phosphate glass, chalcogen glass, or the like, may also be used as the materials thereof. Additionally, other additives may be further included to form a glass having specific physical properties. The additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these elements and other elements. The glass substrate may be distinguished from organic insulating materials including glass fiber (e.g., Glass Fiber, Glass Cloth or Glass Fabric), for example, Copper Clad Laminate (CCL), Prepreg (PPG), or the like. For example, the glass substrate may include plate glass.

The via structure 150 may include a glass layer 151, a first optical waveguide pattern 152 disposed on the glass layer 151, and a dielectric layer 153 disposed on the glass layer 151 and covering at least a portion of the first optical waveguide pattern 152. The glass layer 151 may include the glass described above. For example, the glass layer 151 may also include plate glass. The first optical waveguide pattern 152 is a pattern capable of guiding optical power and may be used for transmitting optical signals. The first optical waveguide pattern 152 may include a transparent dielectric. The transparent dielectric may include a polymer, but the present disclosure is not limited thereto, and may include other materials capable of guiding optical power. For example, the transparent dielectric may include glass, lithium naobenite (LiNbO₃), lithium tantalate (LiTaO₃), and III-V group semiconductor compounds. The dielectric layer 153 may protect the first optical waveguide pattern 152. The dielectric layer 153 may include the transparent dielectric described above. However, the dielectric layer 153 may have a lower refractive index than that of the first optical waveguide pattern 152. Accordingly, the optical signal transmitted through the first optical waveguide pattern 152 may be prevented from being transmitted to the outside.

The second and third optical waveguide patterns 162 and 172 are patterns of guiding optical power, and may be used for transmitting optical signals. Each of the second and third optical waveguide patterns 162 and 172 may include the transparent dielectric described above. If necessary, a protective layer may be further disposed to cover each of the second and third optical waveguide patterns 162 and 172. The protective layer may include the transparent dielectric described above. However, the protective layer may have a lower refractive index than those of the second and third optical waveguide patterns 162 and 172. Accordingly, the optical signal transmitted through the second and third optical waveguide patterns 162 and 172 may be prevented from being transmitted to the outside.

The filler 115 may fill a remaining space of the cavity H and may fix the via structure 150. The filler 115 may include various insulating materials, and may preferably include the transparent dielectric described above. However, the filler 115 may also have a lower refractive index than that of the first optical waveguide pattern 152. Accordingly, the optical signal transmitted through the first optical waveguide pattern 152 may be prevented from being transmitted to the outside.

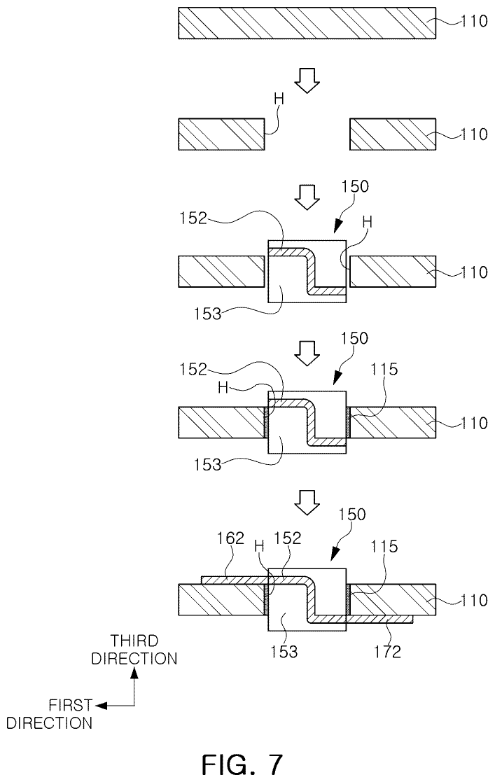

FIG. 7 is a process diagram schematically illustrating an example of manufacturing the printed circuit board of FIG. 3.

Referring to FIG. 7, first, a substrate 110 may be prepared. Next, a cavity H may be formed in the substrate 110. The cavity H may be formed in a chemical method or a mechanical method depending on the material of the substrate 110. For example, etching, blasting, laser, plasma, or the like, may be used. Next, a via structure 150 may be inserted substantially vertically into the cavity H. Next, a remaining space of the cavity H may be filled with a filler 115. For example, a plugging process may be performed. Next, second and third optical waveguide patterns 162 and 172 connected to a first optical waveguide pattern 152 of the via structure 150 may be formed on an upper surface and a lower surface of the substrate 110, respectively. The second and third optical waveguide patterns 162 and 172 may be formed by patterning a photosensitive transparent dielectric using a photolithography process. If necessary, a protective layer covering the second and third optical waveguide patterns 162 and 172 may be further formed, and the protective layer may also include a transparent dielectric.

Other descriptions may be substantially the same as those described in the printed circuit board 100A according to an example embodiment described above, and therefore, duplicate descriptions thereof will be omitted.

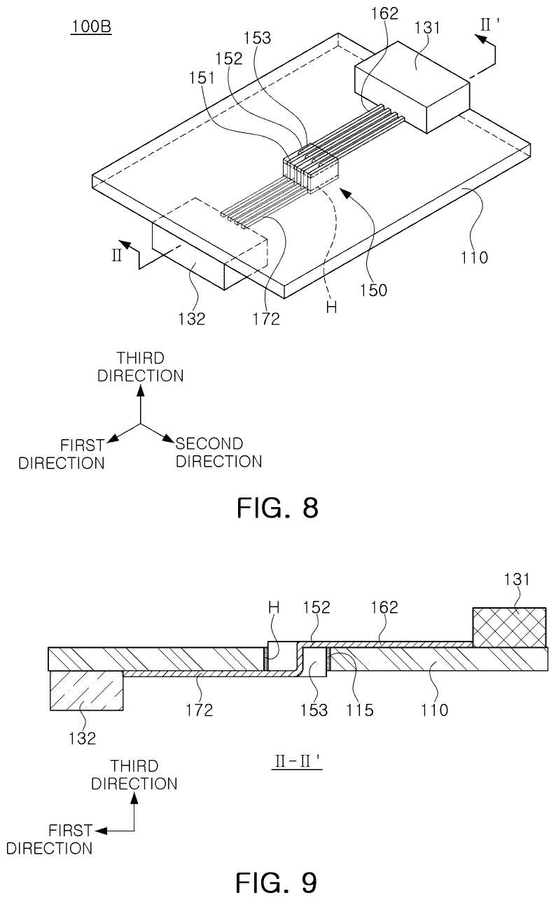

FIG. 8 is a perspective view schematically illustrating another example of a printed circuit board.

FIG. 9 is a schematic a cut cross-sectional view taken along line II-II′ of the printed circuit board of FIG. 8.

Referring to the drawing, a printed circuit board 100B according to another example embodiment may further include a first component 131 disposed on the upper surface of a substrate 110 and connected to a second optical waveguide pattern 162, and a second component 132 disposed on a lower surface of the substrate 110 and connected to a third optical waveguide pattern 172, in the printed circuit board 100A according to an example embodiment described above. The first component 131 may include a Photonic Integrated Circuit (PIC), and may be optically connected to the second optical waveguide pattern 162. The PIC may convert an electrical signal into an optical signal, or may convert an optical signal into an electrical signal. The second component 132 may include an Optical Connector (OC) and may be optically connected to the third optical waveguide pattern 172 to enable transmission of optical signals between the OC 132 and the third optical waveguide pattern 172. If necessary, the OC may be directly connected to the first optical waveguide pattern 152.

Other descriptions may be substantially the same as those described in the printed circuit board 100A according to an example embodiment descried above and the manufacturing example thereof, and therefore, duplicate descriptions thereof will be omitted.

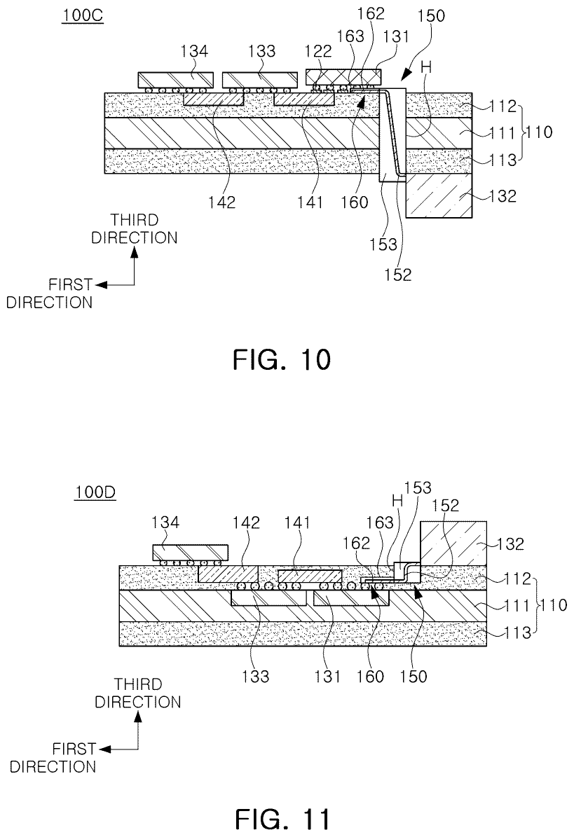

FIG. 10 is a cross-sectional view schematically illustrating another example of a printed circuit board.

Referring to FIG. 10, a printed circuit board 100C according to another example embodiment may include a substrate 110 including a plurality of insulating layers. For example, the substrate 110 may include a glass substrate 111, a first build-up layer 112 disposed on an upper side of the glass substrate 111, and a second build-up layer 113 disposed on a lower side of the glass substrate 111. The first and second build-up layers 112 and 113 may include an organic insulating material, and may include, for example, Prepreg (PPG), an Ajinomoto Build-up Film (ABF), Photoimageable Dielectric (PID), and Solder Resist (SR). Each of the first and second build-up layers 112 and 113 may be formed of a single layer or multiple layers. A cavity H may be a through-cavity penetrating thought an entire substrate 110. A via structure 150 may be inserted into the cavity H. A first pattern structure 160 including a second optical waveguide pattern 162 optically connected to a first optical waveguide pattern 152 of the via structure 150 may be disposed on an upper side of the substrate 110. The first pattern structure 160 may include the second optical waveguide pattern 162 and a first protective layer 163 covering at least a portion of the second optical waveguide pattern 162. The first protective layer 163 may include a transparent dielectric. A wiring pattern 122 may be disposed on the upper side of the substrate 110. A PIC 131 may be disposed on the upper side of the substrate 110, and the PIC 131 may be electrically connected to the wiring pattern 122 to enable transmission of electrical signals between the PIC 131 and the wiring pattern 122, and may be optically connected to the second optical waveguide pattern 162 to enable transmission of optical signals between the PIC 131 and the second optical waveguide 162. For example, the via structure 150 and the PIC 131 may be optically connected without a separate labyrinth structure. An Electronic Integrated Circuit (EIC) 133 electrically connected connected to the PIC 131 and a Logic Integrated Circuit (LIC) 134 electrically connected to the EIC 133 may be further disposed on the upper side of the substrate 110. The EIC 133 may transmit data converted to an electrical signal by the PIC 131 to the LIC 134. The LIC 134 may include an Application Specific Integrated Circuit (ASIC). A first interconnect bridge 141 electrically connecting the PIC 131 and the EIC 133, and a second interconnect bridge 142 electrically connecting the EIC 133 and the LIC 134 may be disposed in the substrate 110. An OC 132 optically connected to the first optical waveguide pattern 152 may be disposed on a lower side of the substrate 110. Wirings and vias for transmitting electric signals may be disposed on or in the substrate 110 in necessary positions.

Other descriptions may be substantially the same as those described in the printed circuit board 100A according to an example embodiment described above and the manufacturing example thereof, and the printed circuit board 100B according to another example embodiment, and therefore, duplicate descriptions thereof will be omitted.

FIG. 11 is a cross-sectional view schematically illustrating another example of a printed circuit board.

Referring to FIG. 11, a printed circuit board 100D according to another example embodiment may include a substrate 110 including a glass substrate 111, a first build-up layer 112 disposed on an upper side of the glass substrate 111, and a second build-up layer 113 disposed on a lower side of the glass substrate 111. The cavity H may be a blind cavity penetrating through a portion of the substrate 110 and having a bottom surface. For example, the cavity H may penetrate through a portion of the first build-up layer 112. A via structure 150 may be inserted into the cavity H, and another portion of the via structure 150 may be in contact with the bottom surface of the cavity H. One end of a first optical waveguide pattern 152 may be partially exposed to one side of a dielectric layer 153 adjacent to a wall surface of the cavity H in another portion of the via structure 150. In the substrate 110, for example, in the first build-up layer 112, a first pattern structure 160 including a second optical waveguide pattern 162 optically connected to the first optical waveguide pattern 152 may be disposed. In the substrate 110, for example, in the glass substrate 111, a PIC 131 may be disposed, and the PIC 131 may be optically connected to the second optical waveguide pattern 162. In the substrate 110, for example, in the glass substrate 111, an EIC 133 electrically connected to the PIC 131 may be disposed. On the substrate 110, an LIC 134 electrically connected to an EIC 133 may be disposed. In the substrate 110, for example, in the first build-up layer 112, a first interconnect bridge 141 electrically connecting the PIC 131 and the EIC 133, and a second interconnect bridge 142 electrically connecting the EIC 133 and the LIC 134 may be disposed. An OC 132 optically connected to the first optical waveguide pattern 152 may be disposed on the substrate 110.

Other descriptions may be substantially the same as those described in the printed circuit board 100A according to an example embodiment described above and the manufacturing example thereof, the printed circuit board 100B according to another example embodiment, and the printed circuit board 100C according to another example embodiment, and therefore, duplicate descriptions thereof will be omitted.

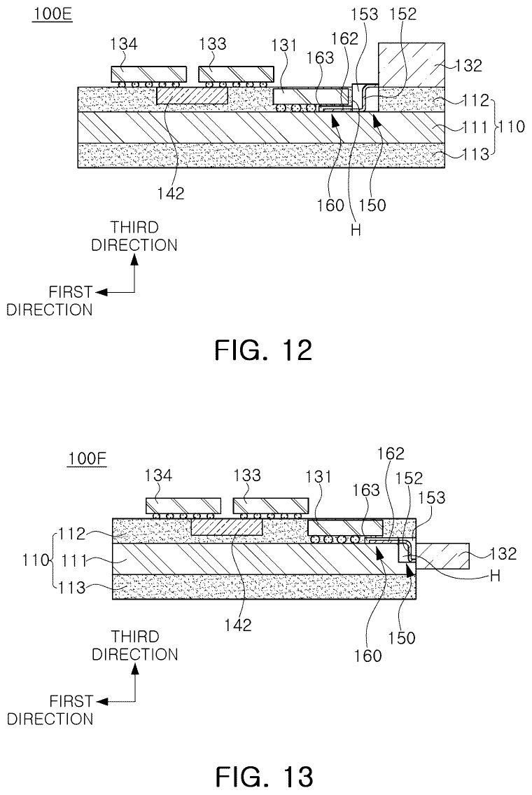

FIG. 12 is a cross-sectional view schematically illustrating another example of a printed circuit board.

Referring to FIG. 12, a printed circuit board 100E according to another example embodiment may also include a substrate 110 including a glass substrate 111, a first build-up layer 112 disposed on an upper side of the glass substrate 111, and a second build-up layer 113 disposed on a lower side of the glass substrate 111. A cavity H may be a blind cavity penetrating a portion of the substrate 110 and having a bottom surface. For example, the cavity H may penetrate through the first build-up layer 112. A via structure 150 may be inserted into the cavity H. A first pattern structure 160 including a second optical waveguide pattern 162 may be disposed in the substrate 110, for example, in the first build-up layer 112. The first pattern structure 160 may be disposed on the glass substrate 111 and may be optically connected to the first optical waveguide pattern 152. A PIC 131 may be disposed in the substrate 110, for example, in the first build-up layer 112, and the PIC 131 may be optically connected to the second optical waveguide pattern 162. On the substrate 110, an EIC 133 electrically connected to the PIC 131 may be disposed. On the substrate 110, an LIC 134 electrically connected to the EIC 133 may be disposed. The PIC 131 and the EIC 133 may be electrically connected through wirings and vias disposed in the substrate 110. In the substrate 110, for example, within the first build-up layer 112, a second interconnect bridge 142 electrically connecting the EIC 133 and the LIC 134 may be disposed. On the substrate 110, an OC 132 optically connected to the first optical waveguide pattern 152 may be disposed.

Other descriptions may be substantially the same as those described in the printed circuit board 100A according to an example embodiment described above and the manufacturing example thereof, the printed circuit board 100B according to another example embodiment, the printed circuit board 100C according to another example embodiment, and the printed circuit board 100D according to another example embodiment, and therefore, duplicate descriptions thereof will be omitted.

FIG. 13 is a cross-sectional view schematically illustrating another example embodiment of a printed circuit board.

Referring to FIG. 13, a printed circuit board 100F according to another example embodiment may also include a substrate 110 including a glass substrate 111, a first build-up layer 112 disposed on an upper side of the glass substrate 111, and a second build-up layer 113 disposed on a lower side of the glass substrate 111. The cavity H may be a blind cavity penetrating through a portion of the substrate 110 and having a bottom surface. For example, the cavity H may penetrate through a portion of the glass substrate 111. A via structure 150 may be inserted into the cavity H. In the substrate 110, for example, in the first build-up layer 112, a first pattern structure 160 including a second optical waveguide pattern 162 may be disposed. The first pattern structure 160 may be disposed on the glass substrate 111, and may be optically connected to a first optical waveguide pattern 152. In the substrate 110, for example, in the first build-up layer 112, a PIC 131 may be disposed, and the PIC 131 may be optically connected to a second optical waveguide pattern 162. An EIC 133 electrically connected to the PIC 131 may be disposed on the substrate 110. An LIC 134 electrically connected to the EIC 133 may be disposed on the substrate 110. The PIC 131 and the EIC 133 may be electrically connected through wirings and vias disposed in the substrate 110. In the substrate 110, for example, in the first build-up layer 112, a second interconnect bridge 142 electrically connecting the EIC 133 and the LIC 134 may be disposed. On the substrate 110, for example, on a side surface of the substrate 110, an OC 132 optically connected to the first optical waveguide pattern 152 may be disposed.

Other descriptions may be substantially the same as those described in the printed circuit board 100A according to an example embodiment described above and the manufacturing example thereof, the printed circuit board 100B according to another example embodiment, the printed circuit board 100C according to another example embodiment, the printed circuit board 100D according to another example embodiment, and the printed circuit board 100E according to another example embodiment, and therefore, duplicate descriptions thereof will be omitted.

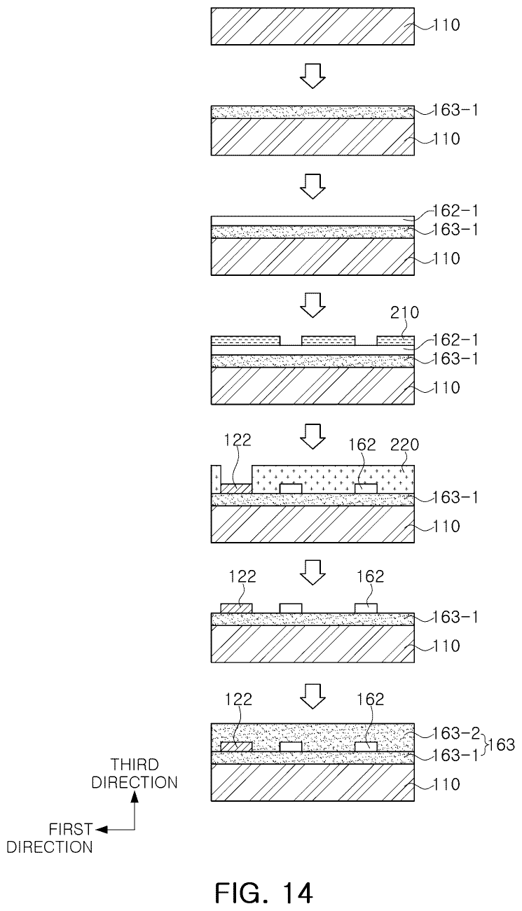

FIG. 14 is a process diagram schematically illustrating an example of forming a wiring pattern for transmitting an electric signal and an optical waveguide pattern for transmitting an optical signal on a substrate.

Referring to FIG. 14, first, a substrate 110 may be prepared. Next, a first transparent dielectric layer 163-1 may be formed on a substrate 110. Next, a second transparent dielectric layer 162-1 may be formed on the first transparent dielectric layer 163-1. The second transparent dielectric layer 162-1 may include a different material from the first transparent dielectric layer 163-1. The second transparent dielectric layer 162-1 may have a higher refractive index than that of the first transparent dielectric layer 163-1. Next, ultraviolet rays may be irradiated to a specific region of a second transparent dielectric layer 162-2 using a first mask 210. Next, the second transparent dielectric layer 162-2 may be developed to form a second optical waveguide pattern 162. Additionally, plating may be performed using a second mask 220 to form a wiring pattern 122. Next, when the second mask 220 is removed, the wiring pattern 122 for transmitting an electric signal and the second optical waveguide pattern 162 for transmitting an optical signal may be formed on the first transparent dielectric layer 163-1. Next, a third transparent dielectric layer 163-2 may be formed on the first transparent dielectric layer 163-1. The second transparent dielectric layer 162-1 may have a higher refractive index than that of the third transparent dielectric layer 163-3. The first and third transparent dielectric layers 163-1 and 163-2 may have substantially the same refractive indices. The first and third transparent dielectric layers 163-1 and 163-2 may include the same material and may be integrated to form a protective layer 163. The protective layer 163 may effectively prevent an optical signal transmitted through the second optical waveguide pattern 162 from being transmitted to the outside.

Other descriptions may be substantially the same as those described in the printed circuit board 100A according to an example embodiment described above and the manufacturing example thereof, the printed circuit board 100B according to another example embodiment, the printed circuit board 100C according to another example embodiment, the printed circuit board 100D according to another example embodiment, the printed circuit board 100E according to another example embodiment, and the printed circuit board 100F according to another example embodiment, and therefore, duplicate descriptions will be omitted.

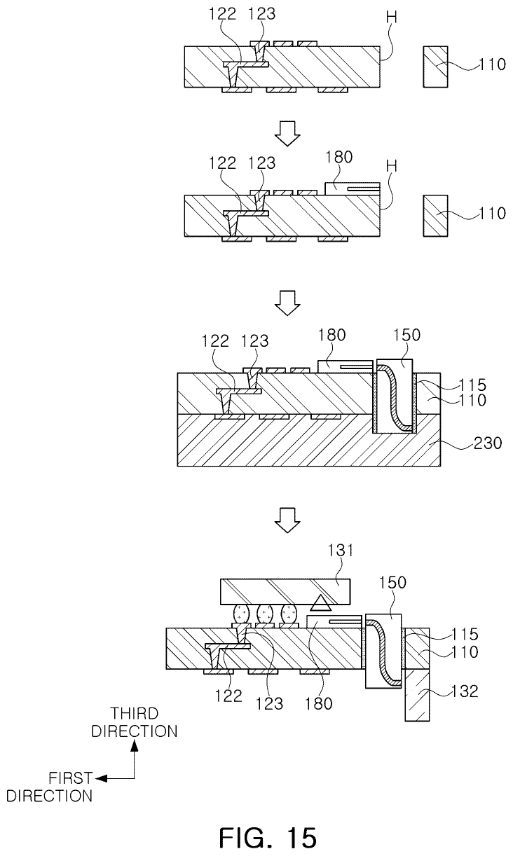

FIG. 15 is a process diagram schematically illustrating an example of manufacturing a printed circuit board using a mirror structure.

Referring to FIG. 15, first, a substrate 110 on which a wiring 122 and a via 123 are formed is prepared, and a cavity H may be formed in the substrate 110. Next, a mirror structure 180 may be disposed on the substrate 110. Next, a via structure 150 may be disposed in the cavity H of the substrate 110 using a jig 230. Additionally, a remaining space of the cavity H of the substrate 110 may be filled with a filler 115. Next, after removing the jig 230, a PIC 131 may be disposed on the upper side of the substrate 110, and an OC 132 may be disposed on the lower side of the substrate 110. The PIC 131 may be optically connected to the via structure 150 through the mirror structure 180. The OC 132 may be optically connected directly to the via structure 150, but the present disclosure is not limited thereto, and may also be connected through a second pattern structure including a third optical guide pattern. In this manner, if necessary, a mirror structure 180 may be used to achieve optical signal connection.

Other descriptions may be substantially the same as those described in the printed circuit board 100A according to an example embodiment and the manufacturing example thereof, the printed circuit board 100B according to another example embodiment, the printed circuit board 100C according to another example embodiment, the printed circuit board 100D according to another example embodiment, the printed circuit board 100E according to another example embodiment, the printed circuit board 100F according to another example embodiment, and therefore, duplicate descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, exposing may include partial exposing as well as a case of complete exposing, and exposure may refer to exposure from embedding a corresponding component. For example, exposing a pad by an opening may be exposing the pad from a resist layer, and a surface treatment layer or the like may be further disposed on the exposed pad.

In the present disclosure, being disposed in a through-portion or a through-hole may include not only cases in which an object is disposed completely in the through-portion or the through-hole, but also cases in which the object partially protrudes therefrom upwardly or downwardly in cross-section. For example, when the object is disposed in the through-portion or the through-hole in plan view, this may be determined in a broader sense.

In the present disclosure, determination may be performed by including process errors, positional deviations, errors at the time of measurement, which may occur substantially in a manufacturing process. For example, being substantially vertical may include not only being completely vertical but also being approximately vertical. Furthermore, being substantially coplanar may include not only a case in which elements are completely on the same plane, but also a case in which the elements are approximately on the same plane.

In the present disclosure, the same insulating material may denote not only the same insulating material but also the same type of insulating material. Accordingly, the compositions of the insulating materials may be substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a substrate having a cavity; and
a via structure at least partially disposed in the cavity and comprising:
a glass layer,
a first optical waveguide pattern disposed on the glass layer, and
a dielectric layer disposed on the glass layer and covering at least a portion of the first optical waveguide pattern.

2. The printed circuit board according to claim 1,
wherein the via structure is at least partially disposed in the cavity so that at least a portion of a surface on which the first optical waveguide pattern of the glass layer is disposed is substantially perpendicular to at least a portion of an upper surface or a lower surface of the substrate.

3. The printed circuit board according to claim 2,
wherein the first optical waveguide pattern includes:
a first end disposed on an upper side of the via structure and partially exposed to a first side surface of the dielectric layer in a first direction, substantially parallel to at least a portion of an upper surface or a lower surface of the substrate;
a second end disposed on a lower side of the via structure and partially exposed to a second side surface of opposite to the first side surface of the dielectric layer in the first direction; and
a connection portion connecting the first end and the second end in a third direction, substantially perpendicular to at least a portion of the upper surface or the lower surface of the substrate,
wherein the connection portion is curved in a portion connected to the first end and the second end, respectively.

4. The printed circuit board according to claim 3,
wherein a stack body in which a plurality of via structures are stacked is inserted into the cavity,
wherein the stack body is substantially parallel to at least a portion of the upper surface or the lower surface of the substrate but includes a structure in which the glass layer, the first optical waveguide pattern, and the dielectric layer are alternately disposed in said order, in a second direction substantially perpendicular to the first direction.

5. The printed circuit board according to claim 3,
wherein a portion of the via structure protrudes upward from the cavity, and
wherein the first end of the first optical waveguide pattern is partially exposed to the first side surface of the dielectric layer from one portion of a protruding portion of the via structure.

6. The printed circuit board according to claim 5,
wherein the cavity is a through-cavity penetrating through the substrate,
wherein another portion of the via structure protrudes downward from the cavity, and
wherein the second end of the first optical waveguide pattern is partially exposed from the other portion of the protruding portion of the via structure to the second side surface of the dielectric layer.

7. The printed circuit board according to claim 5,
wherein the cavity is a blind cavity having a bottom surface,
wherein another portion of the via structure is in contact with the bottom surface of the cavity, and
wherein the second end of the first optical waveguide pattern is partially exposed from another portion of the via structure to the second side surface of the dielectric layer adjacent to a wall surface of the cavity.

8. The printed circuit board according to claim 1,
wherein the first optical waveguide pattern includes a first transparent dielectric, and
wherein the dielectric layer includes a second transparent dielectric.

9. The printed circuit board according to claim 8,
wherein the first transparent dielectric has a refractive index higher than that of the second transparent dielectric.

10. The printed circuit board according to claim 8,
wherein at least a portion of a remaining space excluding a space in which the via structure of the cavity is disposed is filled with a third transparent dielectric,
wherein the first transparent dielectric has a refractive index higher than that of the third transparent dielectric.

11. A printed circuit board, comprising:
a substrate including one or more insulating layers and having a cavity penetrating through at least a portion of at least one of the one or more insulating layers; and
a via structure at least partially disposed in the cavity, and including a first optical waveguide pattern,
wherein the one or more insulating layers include a glass substrate.

12. The printed circuit board according to claim 11,
wherein the first optical waveguide pattern includes:
a first end disposed on an upper side of the via structure and partially exposed to a first side surface of the via structure in a first direction, substantially perpendicular to a stacking direction of the one or more insulating layers;
a second end disposed on a lower side of the via structure and partially exposed to a second side surface of opposite to the first side surface of the via structure in the first direction; and
a connection portion connecting the first end and the second end in a third direction substantially the same as the stacking direction.

13. The printed circuit board according to claim 12, further comprising:
a Photonic Integrated Circuit (PIC) disposed on or in the substrate and optically connected to the first end of the first optical waveguide pattern;
an Electronic Integrated Circuit (EIC) disposed on or in the substrate and electrically connected to the PIC; and
a Logic Integrated Circuit (LIC) disposed on or in the substrate and electrically connected to the EIC.

14. The printed circuit board according to claim 13, further comprising:
a second optical waveguide pattern disposed on or in the substrate and optically connecting the first end of the first optical waveguide pattern and the PIC.

15. The printed circuit board according to claim 13, further comprising:
a mirror structure disposed on or in the substrate and optically connecting the first end of the first optical waveguide pattern and the PIC.

16. The printed circuit board according to claim 13, further comprising:
a first interconnect bridge disposed in the substrate, and electrically connecting the PIC and the EIC; and
a second interconnect bridge disposed in the substrate, and optically connecting the EIC and the LIC.

17. The printed circuit board according to claim 13, further comprising:
an Optical Connector (OC) disposed on or in the substrate, and optically connected to the second end of the first optical waveguide pattern.

18. The printed circuit board according to claim 17, further comprising:
a third optical waveguide pattern disposed on or in the substrate and connecting the second end of the first optical waveguide pattern and the OC.

19. The printed circuit board according to claim 11,
wherein the at least one insulating layer includes the glass substrate, a first build-up layer disposed on an upper side of the glass substrate, and a second build-up layer disposed on a lower side of the glass substrate.

20. The printed circuit board according to claim 11, further comprising:
one or more wiring layers respectively disposed on or in the substrate, and respectively including one or more wirings; and
one or more via layers respectively disposed in the substrate, and respectively connected to at least a portion of at least one of the one or more wiring layers.

21. A via structure for an optical circuit, the via comprising:
a glass layer;
a first optical waveguide pattern disposed on the glass layer; and
a dielectric layer disposed on the glass layer and covering at least a portion of the first optical waveguide pattern,
wherein the via structure is disposed in a cavity in a substrate on which the optical circuit is disposed.

22. The via structure of claim 21, wherein a first end of the first optical waveguide pattern is optically connected to a second optical waveguide or a first optical circuit disposed on a first surface of the substrate, and
a second end of the first optical waveguide pattern is optically connected to a third optical waveguide or a second optical circuit disposed on a second surface of the substrate opposite the first surface.

23. The via structure of claim 21, wherein at least a portion of the via structure extends outside the cavity past a first and/or a second surface of the substrate.

24. The via structure of claim 21, wherein the first optical waveguide pattern comprises a material having a refractive index greater than a material of the glass layer and a material of the dielectric layer.

25. The via structure of claim 21, wherein at least a portion of the first optical waveguide pattern is disposed substantially perpendicularly to surfaces of the substrate.

26. A printed circuit board, comprising:
a plurality of via structures according to claim 21 stacked in a cavity of the printed circuit board such that the first optical waveguide patterns are disposed parallel to each other within the cavity.
